(19) United States
(12) Patent Application Publication
(10) Pub. No.: US 2026/0121610 A1
(43) Pub. Date: Apr. 30, 2026

(54) Substrate, Electronic Device, and Module

(71) Applicant: QUANZHOU SANAN INTEGRATED CIRCUIT CO., LTD., Quanzhou (CN)

(72) Inventors: Xiaoqiang LIN, Quanzhou (CN); Yenfu LIN, Quanzhou (CN)

(21) Appl. No.: 19/365,423

(22) Filed: Oct. 22, 2025

(30) Foreign Application Priority Data
Oct. 29, 2024 (CN) 202411525694.0

(51) Int. Cl. H03H 9/02; H03H 9/145; H05K 1/18

(52) U.S. Cl. CPC H03H 9/02574; H03H 9/14538; H05K 1/185; H05K 2201/1003; H05K 2201/10083

(57) ABSTRACT

The present invention discloses a substrate, an electronic device, and a module. The substrate provided by embodiments comprises a ceramic base having a first surface and a second surface opposite to each other; a doped layer formed in the ceramic base, extending from the first surface toward the second surface in a direction gradually approaching the second surface to a predetermined thickness, wherein the doped layer includes a target dopant element, the doping concentration of which ranges from 1×10\hat{ }17 ions/cm\hat{ }3 to 5×10\hat{ }20 ions/cm \hat{ }3.

### CROSS-REFERENCE TO RELATED APPLICATION

The present disclosure claims priority to Chinese Patent Application No. 202411525694.0 filed on Oct. 29, 2024, the contents of which are herein incorporated by reference in its entirety.

### FIELD

This invention relates to the field of electronic devices and, more particularly, to a substrate, an elastic wave device and a communication module including the elastic wave device.

### BACKGROUND

In some elastic wave devices, for example, surface acoustic wave (SAW) devices employ a composite piezoelectric substrate composed of a ceramic substrate and a piezoelectric material layer, in order to improve temperature characteristics. However, during propagation of waves in the piezoelectric material layer of the surface acoustic wave device, leakage through the ceramic substrate occurs, thereby affecting the quality factor (Q value) and insertion loss of the device.

### SUMMARY

Some examples described herein may have an object to provide a substrate and an electronic device with the substrate, which can effectively improve the Q-factor of electronic devices.

In some examples, a substrate is provided, comprising:
a ceramic base having a first surface and a second surface opposite to each other;
a doped layer formed in the ceramic base, extending from the first surface toward the second surface in a direction gradually approaching the second surface to a predetermined thickness, wherein the doped layer includes a target dopant element, the doping concentration of which ranges from 1×10\hat{ }17 ions/cm\hat{ }3 to 5×10\hat{ }20 ions/cm\hat{ }3.

In some examples, an electronic device is provided, comprising:
a ceramic base having a first surface and a second surface opposite to each other, wherein a doped layer formed in the ceramic base, extending from the first surface toward the second surface in a direction gradually approaching the second surface to a predetermined thickness, wherein the doped layer includes a target dopant element, the doping concentration of which ranges from 1×10\hat{ }17 ions/cm\hat{ }3 to 5×10\hat{ }20 ions/cm\hat{ }3;
a piezoelectric material layer disposed on a side of the first surface opposite to the second surface;
an electrode disposed on a side of the piezoelectric material layer opposite to the ceramic substrate.

In some examples, a module is provided that includes a wiring substrate, a plurality of external connection terminals, an integrated circuit component, an inductor, a sealing portion, and the above-described electronic device.

The embodiments of this invention provide at least one or more of the following advantageous effects: By forming a doped layer containing a target dopant element having a specific doping concentration range on a side of the ceramic substrate close to the piezoelectric material layer, more acoustic wave energy can be confined in the piezoelectric material layer, thereby achieving the effects of improving Q value and insertion loss.

Details of one or more embodiments of the present invention are set forth in the accompanying drawings and the description below. Other features, objects, and advantages of the present invention will become apparent from the description and drawings, and from the claims.

### BRIEF DESCRIPTION OF THE DRAWINGS

The accompanying drawings are intended to provide a further understanding of the present invention, constitute part of this invention, and illustrate exemplary embodiments of this invention. The description and drawings do not limit the scope of the invention.

FIG. 1 is a schematic structural diagram of a ceramic substrate according to an embodiment of the present invention.

FIG. 2 is a schematic structural diagram of a composite piezoelectric substrate according to an embodiment of the present invention.

FIG. 3 is a schematic structural diagram of an electronic device according to an embodiment of the present invention.

FIG. 4 is a schematic process flow diagram for manufacturing the electronic device shown in FIG. 3.

FIG. 5 is a comparative diagram of Q values between Example 1 of the present invention and Comparative Example 1.

FIG. 6 is a comparative diagram of insertion loss between Example 1 of the present invention and Comparative Example 1.

FIG. 7 is a schematic structural diagram of another electronic device according to an embodiment of the present invention.

FIG. 8 is a schematic structural diagram of yet another electronic device according to an embodiment of the present invention.

FIG. 9 is a schematic structural diagram of still another electronic device according to an embodiment of the present invention.

FIG. 10 is a schematic structural diagram of a module according to an embodiment of the present invention.

### DETAILED DESCRIPTION

The embodiments will be described with reference to the accompanying drawings. In the drawings, the same or corresponding parts are denoted by the same reference numerals. Duplicate descriptions of such portions may be simplified or omitted.

Referring to FIG. 3, an embodiment of the present invention provides an electronic device 100, comprising a ceramic substrate 11, a piezoelectric material layer 12, and an electrode 20. Referring to FIG. 1, the ceramic substrate 11 comprises a ceramic material base 110, the ceramic material base 110 having a first surface 111 and a second surface 112 opposite to each other. A doped layer 113 is formed in the ceramic material base 110, extending from the first surface 111 toward the second surface 112 in a direction gradually approaching the second surface 112 to a predetermined thickness. The doped layer 113 comprises a target dopant element doped in the ceramic material base 110. In some embodiments, a doping concentration of the target dopant element in the doped layer 113 ranges from 1×10\hat{ }17 ions/cm\hat{ }3 to 5×10\hat{ }20 ions/cm\hat{ }3. By way of example, it may be 1.67×10\hat{ }17 ions/cm\hat{ }3, 3.33×10\hat{ }17 ions/cm\hat{ }3, 5.33×10\hat{ }18 ions/cm\hat{ }3, 5×10\hat{ }18 ions/cm\hat{ }3, 6.67×10\hat{ }18 ions/cm\hat{ }3, and so on. In the electronic device 100, the piezoelectric material layer 12 is disposed on a side of the first surface 111 opposite to the second surface 112. The piezoelectric material layer 12 and the ceramic substrate 11 together form a composite piezoelectric substrate 10. In the electronic device 100, the electrode 20 is disposed on a side of the piezoelectric material layer 12 opposite to the ceramic substrate 11.

The ceramic material base 110 may be, for example, a polycrystalline material, and specifically may be any one of polycrystalline magnesium aluminate spinel, polycrystalline sapphire, polycrystalline aluminum nitride, polycrystalline magnesium oxide, polycrystalline quartz, and polycrystalline silicon carbide.

In some embodiments, the doped layer 113 is obtained by introducing foreign atoms or ions into the ceramic material base 110 to change the physical, chemical, or electrical properties of the ceramic material base 110, for example, changing the lattice structure (lattice distortion), surface roughness, defect distribution, chemical composition, conductivity, and the like. The doped layer 113 contains constituent elements of the ceramic material base 110, and further contains the target dopant element. Specifically, the doped layer 113 is formed by implanting the target dopant element into the ceramic material base 110 from the first surface 111 toward the inside of the ceramic material base 110, and the doped layer 113 contains all constituent elements of the ceramic material base 110. This may also be understood as the doped layer 113 being based on the ceramic material base 110 and containing the target dopant element. After implanting the target dopant element into the ceramic material base 110, a portion in which the target dopant element is implanted (the upper layer of the ceramic substrate 11 in FIG. 1) forms an amorphous layer (i.e., the doped layer 113), while a portion in which the target dopant element is not implanted (the lower layer of the ceramic substrate 11 in FIG. 1, i.e., the crystal layer 114) retains the original structure of the ceramic material base 110.

The target dopant element may be the same as or different from the constituent elements of the ceramic material base 110. In some embodiments, the target dopant element may be any one or more selected from nitrogen, boron, phosphorus, and carbon. By way of example, when the ceramic material base 110 is polycrystalline magnesium aluminate spinel and the target dopant element is nitrogen, the doped layer 113 is a nitrogen-doped MgAl₂O₄ layer, and the crystal layer 114 is an MgAl₂O₄ layer. The above example of the target dopant element can effectively increase the compressive stress of the surface layer of the ceramic material base 110 (a region extending from the first surface 111 toward the second surface 112 to the predetermined thickness), increase the material hardness and elastic modulus of the surface layer of the obtained ceramic substrate 11, and reduce the mechanical loss of surface acoustic waves during propagation, thereby improving the Q value of the device. The position of the doped layer 113 is from the first surface 111 toward the second surface 112 to the predetermined thickness, i.e., the region in the ceramic material base 110 in which lattice distortion occurs is located in the surface layer of the ceramic material base 110, and has little effect on the deep portion of the ceramic material base 110 (i.e., the region where the crystal layer 114 is located).

Referring to FIG. 3, the predetermined thickness is denoted as D1, and the value of D1 is the distance from the first surface 111 to the interface between the doped layer 113 and the crystal layer 114.

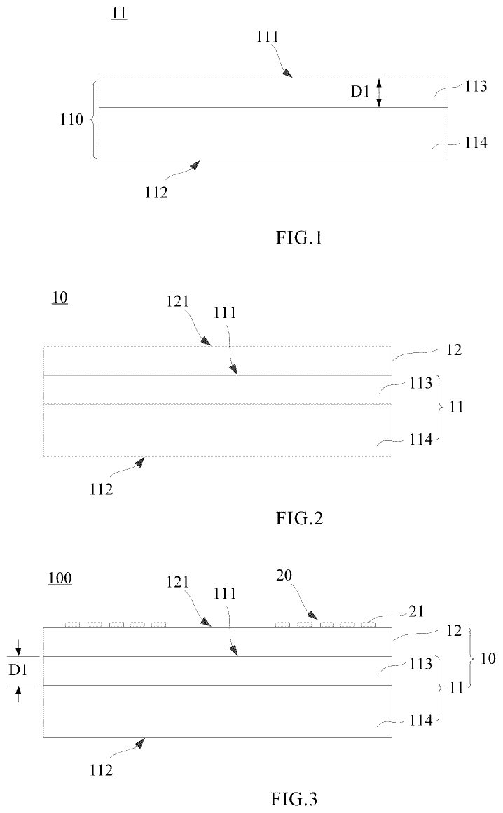

The material of the piezoelectric material layer 12 is different from that of the ceramic substrate 11. Specifically, the piezoelectric material layer 12 is made of lithium tantalate or lithium niobate. The Young's modulus of the piezoelectric material layer 12 is less than the Young's modulus of the ceramic substrate 11. When lithium tantalate is used for the piezoelectric material layer 12, the Young's modulus is 200 to 250 GPa; when lithium niobate is used, the Young's modulus is 170 to 210 GPa. The ceramic substrate 11 and the piezoelectric material layer 12 together constitute the composite piezoelectric substrate 10 shown in FIG. 2, with the orientation shown in FIG. 2 or FIG. 3, namely, the piezoelectric material layer 12 being disposed on the first surface 111 of the ceramic substrate 11. In the composite piezoelectric substrate 10, the doped layer 113 is located between the crystal layer 114 and the piezoelectric material layer 12. The ceramic substrate 11 and the piezoelectric material layer 12 may be directly bonded together via van der Waals force. The piezoelectric material layer 12 includes a third surface 121 opposite to the ceramic substrate 11, and the electrode 20 is disposed on the third surface 121. The electrode 20 may include an IDT electrode 21, which is an interdigital transducer. The electronic device 100 is specifically an elastic wave device, and more specifically, a SAW device.

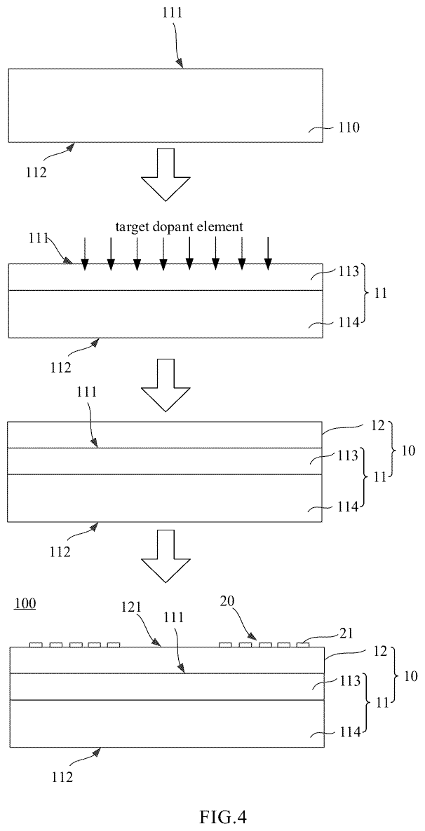

The manufacturing process of the electronic device 100 provided in this embodiment may be carried out with reference to FIG. 4, as follows: (1) providing a ceramic material base 110, the ceramic material base 110 having a first surface 111 and a second surface 112 opposite to each other; (2) injecting a target dopant element from the first surface 111 into the ceramic material base 110 using a doping source containing the target dopant element. For example, when the target dopant element is nitrogen, nitrogen gas may be used as the doping source to bombard the first 30 surface 111. After injecting the target dopant element, two layers, namely the doped layer 113 and the crystal layer 114, are formed in the ceramic material base 110, thereby obtaining the ceramic substrate 11; (3) forming the piezoelectric material layer 12 on the first surface 111 of the ceramic substrate 11. The ceramic substrate 11 and the piezoelectric material layer 12 may be combined by direct bonding, and after bonding, the piezoelectric material layer 12 may be thinned to obtain the composite piezoelectric substrate 10; (4) forming the electrode 20 on the piezoelectric material layer 12 to obtain the electronic device 100. Preferably, no annealing process is required between steps (2) and (4), and it is preferable to prevent void formation in the ceramic substrate 11 to avoid degradation of the Q value caused by voids.

In some embodiments, the Young's modulus of the ceramic substrate 11 is 294 to 392 GPa. In some embodiments, the Young's modulus of the ceramic substrate 11 is greater than the Young's modulus of the ceramic material base 110. The fact that the Young's modulus of the ceramic substrate 11 is greater than that of the ceramic material base 110 can also be understood as meaning that the portion forming the doped layer 113 has a higher Young's modulus than the ceramic material base 110 before doping (also referred to as the original ceramic material base), thereby causing the overall Young's modulus of the ceramic substrate 11 to increase compared to that of the ceramic material base 110 before doping. The Young's modulus of the ceramic material base 110 can be determined by testing the constituent material of the ceramic material base 110. For example, when the ceramic material base 110 is polycrystalline magnesium aluminate spinel, the Young's modulus of the ceramic material base 110 can be determined based on that of polycrystalline magnesium aluminate spinel. For example, the Young's modulus of the ceramic material base 110 may be 278 to 280 GPa, and after forming the doped layer 113, the Young's modulus of the ceramic substrate 11 increases to 294 to 392 GPa (by way of example, it may be 294 GPa, 300 GPa, 320 GPa, 370 GPa, etc.). In this embodiment, by forming the doped layer 113 containing the target dopant element in the ceramic substrate 11, the ceramic material base is modified such that the Young's modulus of the side of the ceramic substrate 11 facing the piezoelectric material layer 12 is increased, thereby confining more acoustic wave energy in the piezoelectric material layer 12 and achieving an improvement in Q value.

In some embodiments, the Young's modulus of the ceramic substrate 11 is 1.05 to 1.5 times the Young's modulus of the ceramic material base 110. By way of example, it may be 1.05 times, 1.1 times, 1.2 times, or 1.4 times, but is not limited to these examples. Within the multiplicative range provided in this embodiment, as the multiple increases, the difference in Young's modulus between the ceramic substrate 11 and the original ceramic material base 110 also increases. Controlling the Young's modulus of the ceramic substrate 11 to within 1.5 times that of the ceramic material base 110 can prevent spurious responses or other abnormal parameters. In some embodiments, the Young's modulus of the ceramic substrate 11 is greater than 300 GPa, which is more advantageous for improving the Q value of the electronic device.

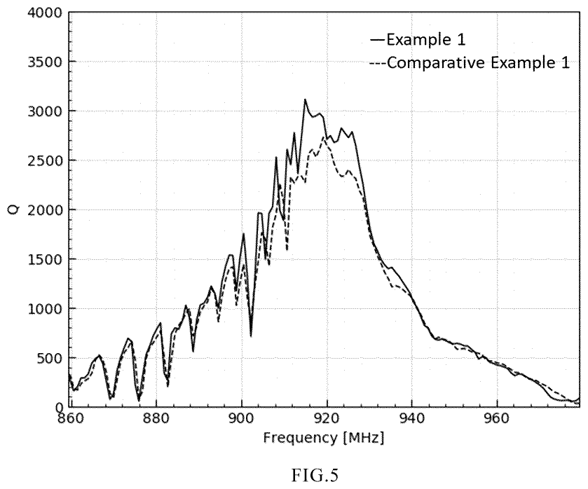

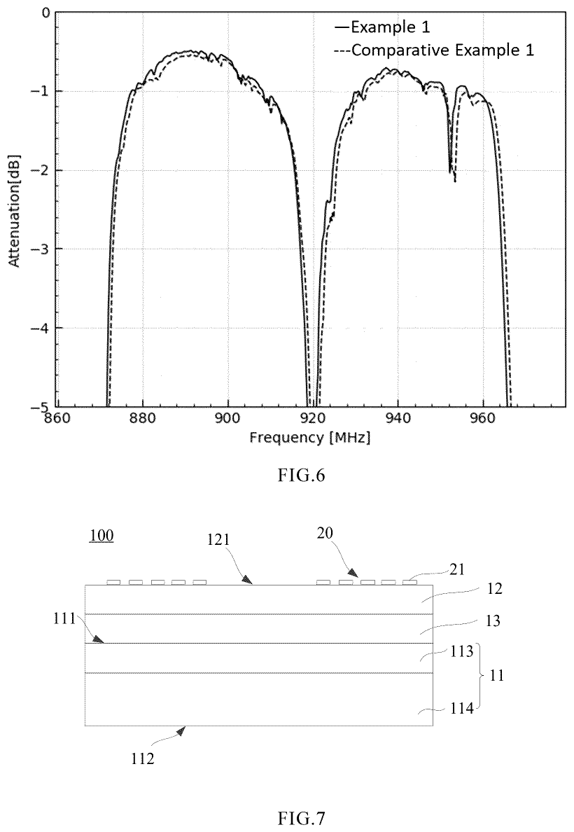

The comparison between Example 1 and Comparative Example 1 of the present invention with respect to Q value and insertion loss can be seen in FIG. 5 and FIG. 6. In Example 1, which is an embodiment of the electronic device 100 of the present invention, the predetermined thickness D1 of the doped layer 113 is 121.6 nm. In Comparative Example 1, the ceramic substrate 11 does not have a doped layer, while other parameters remain the same. In FIG. 5, the horizontal axis represents frequency (MHz), and the vertical axis represents Q value. As can be seen from FIG. 5, the Q value of Example 1 is significantly higher than that of Comparative Example 1 in the range of 900 MHz to 930 MHz. The maximum Q value in Example 1 is 3255.5, while the maximum Q value in Comparative Example 1 is 2729.0, representing a 19% improvement in Q value for Example 1 over Comparative Example 1. In FIG. 6, the horizontal axis represents frequency (MHz), and the vertical axis represents insertion loss (dB). As can be seen from FIG. 6, the minimum insertion loss in Example 1 is −0.499 dB, while that in Comparative Example 1 is −0.542 dB. The minimum insertion loss in Example 1 is improved by 0.043 dB compared to Comparative Example 1. The minimum insertion loss of Example 1 demonstrates an 8.6% improvement compared to Comparative Example 1. Therefore, the electronic device 100 provided in the embodiment of the present invention can achieve better electrical performance.

In some embodiments, the predetermined thickness D1 is 0.025λ to 2λ, where λ is a wavelength of an elastic wave determined by the electrode pitch of the IDT electrode 21. By way of example, D1 may be 0.05λ, 0.1λ, 0.15λ, 0.3λ, 0.5λ, 0.8λ, 1.2λ, 1.5λ, 2.0λ, and so on. In some embodiments, the predetermined thickness D1 is 0.025λ to λ, and more specifically, may be 0.025λ to 0.5λ. Within the predetermined thickness range provided in this embodiment, it is possible to effectively prevent leakage of acoustic wave energy of the fundamental mode and scattering of spurious higher-order modes, thereby preventing the generation of spurious responses.

Table 1 shows the parameters of the electronic devices 100 provided in some embodiments (Examples 2 to 5) of the present invention (the Young's modulus refers to the Young's modulus of the ceramic substrate 11 forming the electronic device 100, and insertion loss is represented by minimum insertion loss).

TABLE 1

| | Example 2 | Example 3 | Example 4 | Example 5 |
|---|---|---|---|---|
| Ceramic | Spinel | Spinel | Spinel | Spinel |
| material base | | | | |
| Target dopant | N | N | N | N |
| element | | | | |
| Predetermined | 0.050λ | 0.063λ | 0.077λ | 0.089λ |
| thickness | | | | |
| Young's | 308 | 360 | 382 | 390 |
| modulus (GPa) | | | | |
| Maximum Q | 3084 | 3256 | 3165 | 3138 |
| value | | | | |
| Insertion loss | −0.504 | −0.499 | −0.508 | −0.497 |

According to the data in Table 1, after forming the doped layer 113 in the electronic device 100 provided in this embodiment, the Young's modulus of the ceramic substrate 11 reaches more than 300 GPa, and as the predetermined thickness of the formed doped layer 113 increases, the Young's modulus of the obtained ceramic substrate 11 also increases. The electronic devices 100 provided in Examples 2 to 5 all have relatively high Q values and low insertion loss.

In some embodiments, the concentration range of the target dopant element in the doped layer 113 is specifically 5×10\hat{ }17 ions/cm\hat{ }3 to 1×10\hat{ }20 ions/cm\hat{ }3, which can achieve a good effect in improving the Q value while avoiding an excessive increase in warpage of the ceramic substrate 11 caused by an excessively high doping concentration. This ensures that the ceramic substrate 11 has good bonding performance during subsequent bonding with the piezoelectric material layer 12, and also prevents excessive damage to the surface or interior of the ceramic material base 110 during formation of the doped layer 113, thereby maintaining the material properties of the ceramic substrate 11. In some embodiments, the warpage of the ceramic substrate 11 having the doped layer 113 is 10 to 14 μm, which is larger than that of a conventional ceramic substrate, but can ensure better performance during subsequent bonding while greatly improving the Q value.

Referring to FIG. 7, in another embodiment of the present invention, the electronic device 100 (composite piezoelectric substrate 10) further includes an intermediate layer 13 located between the piezoelectric material layer 12 and the ceramic substrate 11. The acoustic velocity of the intermediate layer 13 is lower than that of the piezoelectric material layer 12. That is, compared with bulk waves propagating in the piezoelectric material layer 12, the bulk waves in the intermediate layer 13 have a lower acoustic velocity. In this embodiment, by providing the intermediate layer 13 having a low acoustic velocity, the acoustic velocity of the elastic waves can be reduced, so that the energy of the elastic waves is concentrated in the low-velocity medium (i.e., the intermediate layer 13), thereby reducing loss and improving the Q value.

The material of the intermediate layer 13 may be any one of silicon dioxide, silicon oxynitride, tantalum oxide, or a material containing one of these materials as the main component. In some embodiments, the intermediate layer 13 is made of silicon dioxide, and the piezoelectric material layer 12 is made of lithium tantalate. Lithium tantalate has a negative temperature characteristic of elastic constants, while silicon dioxide has a positive temperature characteristic, which can reduce the absolute value of the TCF (temperature coefficient of frequency) of the elastic wave device. Furthermore, the inherent acoustic impedance of silicon dioxide is lower than that of lithium tantalate, and therefore the electromechanical coupling coefficient of the electronic device can be increased.

In some embodiments, the thickness of the intermediate layer 13 is greater than or equal to 0.5λ, where λ is the wavelength of the elastic wave determined by the electrode pitch of the IDT electrode 21. Specifically, the thickness of the intermediate layer 13 may be 0.6 to 0.8λ. In some embodiments, the thickness of the piezoelectric material layer 12 is less than or equal to 2λ. Specifically, the thickness of the piezoelectric material layer 12 may be less than 1λ. In one specific embodiment, A is 2.25 μm, the thickness of the piezoelectric material layer 12 is 0.1λ to 1λ, and the thickness of the intermediate layer 13 is 0.6λ.

The electronic device 100 provided in this embodiment may adopt CSP (Chip Scale Package) packaging or WLP (Wafer Level Package) packaging.

For example, referring to FIG. 8, which is a schematic structural diagram of an electronic device 100 using CSP packaging, the electronic device 100 includes a component (including the composite piezoelectric substrate 10 and the electrode 20), a package substrate 30, a first sealing structure 41, and a first external terminal electrode 53. The package substrate 30 is disposed opposite to the surface of the component where the electrode 20 is located (i.e., the third surface 121 of the piezoelectric material layer 12), and a gap 60 is formed between the package substrate 30 and the third surface 121. The first sealing structure 41 is disposed on a side of the package substrate 30 facing the component, covering the side surface of the component and the surface opposite to the package substrate 30, so as to seal the gap 60 and hermetically seal the component. The electrode 20 includes an electrode pad 22 electrically connected to the IDT electrode 21. The electrode pad 22 is electrically connected to a first conductive portion 52 in a wiring pattern on the package substrate 30 via a bump 51. The first conductive portion 52 is electrically connected to a first external terminal electrode 53 on a side of the package substrate 30 opposite to the component, so that the electronic device 100 can be electrically connected to an external device via the first external terminal electrode 53.

The materials of the package substrate 30 and the first sealing structure 41 may be selected from common substrate materials and sealing materials used in existing CSP packaging. The electrode pad 22, the bump 51, the first conductive portion 52, and the first external terminal electrode 53 are all made of materials having good electrical conductivity. The present embodiment is not limited to the above examples.

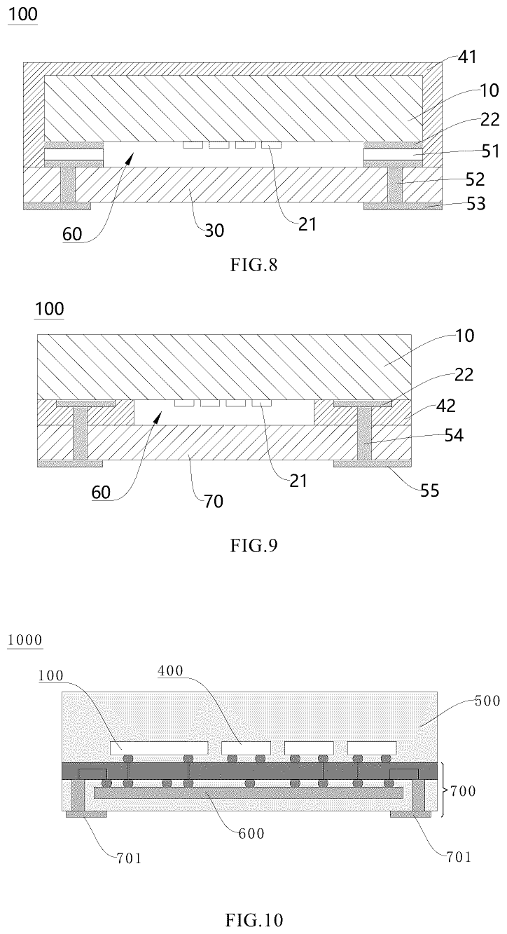

Referring to FIG. 9, which is a schematic structural diagram of an electronic device 100 using WLP packaging, the electronic device 100 includes a component (including the composite piezoelectric substrate 10 and the electrode 20), a cover 70, a second sealing structure 42, and a second external terminal electrode. The cover 70 is disposed opposite to the surface of the component where the electrode 20 is located (i.e., the third surface 121 of the piezoelectric material layer 12), and a gap 60 is formed between the cover 70 and the third surface 121. The electrode 20 includes an electrode pad 22 electrically connected to the IDT electrode 21. The region on the third surface 121 where the IDT electrode 21 is disposed is referred to as the active region. The second sealing structure 42 is disposed between the cover 70 and the component and is arranged around the active region. The second sealing structure 42 surrounds the electrode pad 22 so as to seal the component. The second external terminal electrode 55 disposed on the surface of the cover 70 opposite to the component is connected to the electrode pad 22 via a second conductive portion 54 passing through the cover 70 and the second sealing structure 42, so that the electronic device 100 can be electrically connected to an external device via the second external terminal electrode 55.

The materials of the cover 70 and the second sealing structure 42 may be selected from cover materials and sealing materials used in existing WLP packaging. The electrode pad 22, the second conductive portion 54, and the second external terminal electrode 55 are all made of materials having good electrical conductivity. The present embodiment is not limited to these examples.

Referring to FIG. 10, the invention further provides a module 1000, comprising a wiring substrate 700, a plurality of external connection terminals 701, an integrated circuit component 600, an electronic device 100 (including the composite piezoelectric substrate 10), an inductor 400, and a sealing portion 500. The plurality of external connection terminals 701 are formed on one surface of the wiring substrate 700, and the plurality of external connection terminals 701 are mounted on a motherboard of a predetermined mobile communication terminal. The integrated circuit component 600 (which may be referred to as an IC) is mounted inside the wiring substrate 700. The integrated circuit component 600 includes a switching circuit and a low-noise amplifier. The electronic device 100 is mounted on a main surface of the wiring substrate 700. The inductor 400 is used for impedance matching and, by way of example, the inductor 400 is an integrated passive device (IPD). The sealing portion 500 is used to seal multiple electronic components, including the electronic device 100, on the wiring substrate 700.

The module 1000 provided in this embodiment includes the electronic device 100, and therefore also includes the ceramic substrate 11, and has the same effects as the ceramic substrate 11, which will not be repeated here.

The foregoing description merely represents preferred embodiments of the present invention and is not intended to limit the invention in any way. Although the invention has been disclosed through the above embodiments, those skilled in the art may make minor modifications or equivalent changes without departing from the scope of the invention. All such modifications, equivalent alterations, and improvements shall fall within the scope of the present invention as defined by its technical essence. Of course, the present invention is not limited to the embodiments described above, but rather encompasses all embodiments capable of achieving the objectives of the invention. It should be understood that the present invention includes all implementations that achieve the objectives described herein, and is not restricted solely to the specific embodiments disclosed.

Although various aspects of some embodiments have been described, it will be readily apparent to those skilled in the art that various modifications, improvements, and enhancements may be made. Such modifications, improvements, and enhancements are intended to be part of the invention and fall within the scope of this disclosure.

It should be understood that the embodiments of the methods and devices described herein are not limited to the configurations and arrangements illustrated or described above. The methods and devices may be realized in other forms and may be implemented or carried out in various ways.

The specific examples provided are for illustrative purposes only and are not intended to be limiting in any way.

The expressions and terms used in this disclosure are for the purpose of illustration and should not be construed as limiting. Terms such as “comprise,” “include,” “have,” “contain,” and variations thereof are intended to include the items listed thereafter as well as equivalents and additional items.

References to “or” are intended to be inclusive, meaning that any of the listed terms may apply individually, in combination, or collectively.

Directional expressions such as front, back, top, bottom, left, right, vertical, horizontal, inside, and outside are used merely for the sake of descriptive convenience. Such expressions do not restrict the components of the invention to any particular spatial position or orientation. Accordingly, the above descriptions and drawings are merely illustrative in nature.

1. A substrate, comprising:
a ceramic base having a first surface and a second surface opposite to each other;
a doped layer formed in the ceramic base, extending from the first surface toward the second surface in a direction gradually approaching the second surface to a predetermined thickness, wherein the doped layer includes a target dopant element, the doping concentration of which ranges from 1×10\hat{ }17 ions/cm\hat{ }3 to 5×10\hat{ }20 ions/cm\hat{ }3.

2. The substrate according to claim 1, wherein the target dopant element is selected from the group consisting of nitrogen, boron, phosphorus, carbon, and combinations thereof.

3. The substrate according to claim 1, wherein the ceramic base is selected from the group consisting of polycrystalline magnesium aluminate spinel, polycrystalline sapphire, polycrystalline aluminum nitride, polycrystalline magnesium oxide, polycrystalline quartz, and polycrystalline silicon carbide.

4. The substrate according to claim 1, wherein the ceramic base has a Young's modulus ranging from 294 GPa to 392 GPa.

5. The substrate according to claim 1, further comprising a piezoelectric material layer disposed on a side of the first surface opposite to the second surface.

6. The substrate according to claim 5, further comprising an intermediate layer disposed between the first surface and the piezoelectric material layer, wherein an acoustic velocity of the intermediate layer is lower than an acoustic velocity of the piezoelectric material layer.

7. An electronic device, comprising:
a ceramic base having a first surface and a second surface opposite to each other, wherein a doped layer formed in the ceramic base, extending from the first surface toward the second surface in a direction gradually approaching the second surface to a predetermined thickness, wherein the doped layer includes a target dopant element, the doping concentration of which ranges from 1×10\hat{ }17 ions/cm\hat{ }3 to 5×10\hat{ }20 ions/cm\hat{ }3;
a piezoelectric material layer disposed on a side of the first surface opposite to the second surface;
an electrode disposed on a side of the piezoelectric material layer opposite to the ceramic substrate.

8. The electronic device according to claim 7, wherein the electrode is an IDT electrode, the predetermined thickness is 0.025λ to 2λ, and λ is a wavelength of an elastic wave determined by an electrode pitch of the IDT electrode.

9. The electronic device according to claim 7, further comprising an intermediate layer disposed between the first surface and the piezoelectric material layer, wherein an acoustic velocity of the intermediate layer is lower than an acoustic velocity of the piezoelectric material layer.

10. The electronic device according to claim 9, wherein the electrode is an IDT electrode, and a thickness of the intermediate layer is greater than or equal to 0.5λ, wherein λ is a wavelength of an elastic wave determined by an electrode pitch of the IDT electrode.

11. The electronic device according to claim 7, wherein the electrode is an IDT electrode, and a thickness of the piezoelectric material layer is less than or equal to 2λ, wherein λ is a wavelength of an elastic wave determined by an electrode pitch of the IDT electrode.

12. The electronic device according to claim 7, wherein the ceramic base is selected from the group consisting of polycrystalline magnesium aluminate spinel, polycrystalline sapphire, polycrystalline aluminum nitride, polycrystalline magnesium oxide, polycrystalline quartz, and polycrystalline silicon carbide.

13. The electronic device according to claim 7, wherein the target dopant element is selected from the group consisting of nitrogen, boron, phosphorus, carbon, and combinations thereof.

14. The electronic device according to claim 7, wherein the doped layer is formed by introducing foreign atoms or ions into the ceramic base to alter its physical, chemical, or electrical properties.

15. The electronic device according to claim 7, wherein the doped layer is an amorphous layer, and a lower layer beneath the doped layer in the ceramic substrate is a crystalline layer.

16. The electronic device according to claim 7, wherein the ceramic base is polycrystalline magnesium aluminate spinel and the target dopant element is nitrogen.

17. The electronic device according to claim 7, wherein the piezoelectric material layer is directly bonded to the ceramic base.

18. A module, comprising a wiring substrate, a plurality of external connection terminals, an inductor, a sealing portion, and the electronic device according to claim 7.

19. The module according to claim 18, wherein the ceramic base is selected from the group consisting of polycrystalline magnesium alumninate spinel, polycrystalline sapphire, polycrystalline aluminum nitride, polycrystalline magnesium oxide, polycrystalline quartz, and polycrystalline silicon carbide, and the target dopant element is selected from the group consisting of nitrogen, boron, phosphorus, carbon, and combinations thereof.

20. The module according to claim 18, wherein the doped layer is an amorphous layer, and a lower layer beneath the doped layer in the ceramic substrate is a crystalline layer.
